(19) United States
(12) Patent Application Publication
(10) Pub. No.: US 2026/0209646 A1
(43) Pub. Date: Jul. 23, 2026

(54) WORKPIECE PROCESSING METHOD, REMOVAL LIQUID FOR REMOVING BORON-CONTAINING SUBSTANCE, AND SUBSTRATE PROCESSING METHOD

(71) Applicant: TOKYO OHKA KOGYO CO., LTD., Kawasaki-shi (JP)

(72) Inventor: Emi UCHIDA, Kawasaki-shi (JP)

(21) Appl. No.: 19/158,170

(22) PCT Filed: Mar. 4, 2024
(86) PCT No.: PCT/JP2024/008019

§ 371 Date: Aug. 20, 2025

(30) Foreign Application Priority Data
Mar. 7, 2023 (JP) 2023-034601

(51) Int. Cl. C11D 3/39; H10P 50/00; H10P 50/68

(52) U.S. Cl. CPC C11D 3/3942; H10P 50/683; H10P 50/73

(57) ABSTRACT

A workpiece processing method including bringing a boron-containing substance removal liquid containing orthoperiodic acid and water into contact with a workpiece containing a boron-containing substance to remove the boron-containing substance. The removal liquid contains orthoperiodic acid and water and is used for removing a boron-containing substance from a workpiece containing the boron-containing substance.

### TECHNICAL FIELD

The present invention relates to a workpiece processing method, a removal liquid for removing a boron-containing substance, and a substrate processing method.

Priority is claimed on Japanese Patent Application No. 2023-034601, filed Mar. 7, 2023, the amount of which is incorporated herein by reference.

### BACKGROUND ART

In the related art, an amorphous silicon film or an amorphous carbon film has been used as a hard mask used for etching processing of a semiconductor substrate. However, the amorphous silicon film or the amorphous carbon film has low dry etching resistance. Therefore, in a case where these films are used as a hard mask, it is necessary to form thick films having a thickness of 1 μm or greater. In recent years, boron-based materials have been attracting attention as hard mask materials having higher dry etching resistance than the amorphous silicon film or the amorphous carbon film.

The hard mask needs to be removed after functioning as a hard mask. In the related art, the amorphous silicon film or the amorphous carbon film used as a hard mask material is removed by O₂ plasma. However, a boron film has high resistance to O₂ plasma and is difficult to remove by O₂ plasma. Therefore, a method of removing a boron film with a chemical liquid has been examined.

Patent Document 1 describes that a boron-rich layer is removed using a chemical liquid such as HF:H₂O₂, high-temperature H₃PO₄, or H₂SO₄:H₂O₂. Patent Document 2 describes that a boron single film is removed using ozone water, hydrogen peroxide water, a mixed solution of nitric acid, sulfuric acid, and water, or the like.

### CITATION LIST

### Patent Documents

Patent Document 1: Published Japanese Translation No. 2013-533376 of the PCT International Publication for Patent Applications
Patent Document 2: Japanese Patent No. 7142461

### SUMMARY OF INVENTION

### Technical Problem

In the chemical liquid described in Patent Document 1 or 2, a high-temperature processing at 75° C. or higher may be required in the processing of removing the boron-containing film. In addition, in the chemical liquid described in Patent Document 1 or 2, the time until inactivation may be shortened in a case where the temperature is increased. In this case, it is necessary to heat the chemical liquid to the processing temperature immediately before use, which causes a limitation in terms of operation.

In addition, the boron-containing film removal liquid is preferably a liquid that does not damage a conductive material.

The present invention has been made in consideration of the above-described circumstances, and an object of the present invention is to provide a workpiece processing method that enables a boron-containing substance to be removed efficiently, a removal liquid for removing a boron-containing substance, which is used in the processing method, and a substrate processing method using the removal liquid.

### Solution to Problem

In order to solve the above-described problems, the present invention has adopted the following configurations.

According to a first aspect of the present invention, there is provided a workpiece processing method including: a step of bringing a boron-containing substance removal liquid containing orthoperiodic acid and water into contact with a workpiece containing a boron-containing substance to remove the boron-containing substance from the workpiece.

According to a second aspect of the present invention, there is provided a removal liquid including: orthoperiodic acid; and water, in which the removal liquid is used for removing a boron-containing substance from a workpiece containing the boron-containing substance.

According to a third aspect of the present invention, there is provided a substrate processing method including: a step of forming an etching mask including a boron-containing film on a substrate; a step of performing etching on the substrate using the etching mask; and a step of bringing the removal liquid according to the second aspect into contact with the boron-containing film after the etching to remove the boron-containing film.

### Advantageous Effects of Invention

According to the present invention, it is possible to provide a workpiece processing method that enables a boron-containing substance to be removed efficiently, a removal liquid for removing a boron-containing substance, which is used in the processing method, and a substrate processing method using the removal liquid.

### BRIEF DESCRIPTION OF DRAWINGS

FIG. 1A A schematic view showing an example of a workpiece including a boron-containing film before being used as an etching mask, to which a workpiece processing method of one embodiment is applied.

FIG. 1B A schematic view showing an example of a workpiece including a boron-containing film before being used as an etching mask, to which the workpiece processing method of one embodiment is applied.

FIG. 2 A schematic view showing an example of a workpiece including a boron-containing film after being used as an etching mask, to which the workpiece processing method of one embodiment is applied.

FIG. 3A A schematic view for describing one step of a substrate processing method according to one embodiment.

FIG. 3B A schematic view for describing one step of the substrate processing method according to the embodiment.

FIG. 3C A schematic view for describing one step of the substrate processing method according to the embodiment.

FIG. 3D A schematic view for describing one step of the substrate processing method according to the embodiment.

### DESCRIPTION OF EMBODIMENTS

### (Workpiece Processing Method)

A workpiece processing method according to a first aspect of the present invention includes a step of bringing a boron-containing substance removal liquid containing orthoperiodic acid and water into contact with a workpiece containing a boron-containing substance to remove the boron-containing substance from the workpiece (hereinafter, also referred to as “step A”).

[Step of Removing Boron-Containing Substance from Workpiece: Step A]

The step A is a step of bringing a boron-containing substance removal liquid containing orthoperiodic acid and water into contact with a workpiece containing a boron-containing substance to remove the boron-containing substance from the workpiece.

### <Boron-Containing Substance Removal Liquid>

The boron-containing substance removal liquid used in the step A contains orthoperiodic acid and water.

### <<Orthoperiodic Acid>>

The boron-containing substance removal liquid contains orthoperiodic acid (H₅IO₆). The boron-containing substance removal liquid contains orthoperiodic acid as an oxidizing agent, and thus exhibits high boron-containing substance removal performance even at a temperature of 60° C. or lower.

The amount of the orthoperiodic acid in the boron-containing substance removal liquid is not particularly limited, but is, for example, 0.01% to 70% by mass with respect to the total mass of the boron-containing substance removal liquid. From the viewpoint of removal efficiency of the boron-containing substance, the amount of the orthoperiodic acid is preferably 0.05% by mass or greater, more preferably 0.1% by mass or greater, still more preferably 0.2% by mass or greater, even still more preferably 0.5% by mass or greater, and particularly preferably 1% by mass or greater with respect to the total mass of the boron-containing substance removal liquid. From the viewpoint of safety and the like, the amount of the orthoperiodic acid is preferably 50% by mass or less, more preferably 30% by mass or less, still more preferably 25% by mass or less, even still more preferably 10% by mass or less, and particularly preferably 5% by mass or less. The upper limit values and the lower limit values can be optionally combined. The amount of the orthoperiodic acid is preferably 0.1% to 50% by mass with respect to the total mass of the boron-containing substance removal liquid.

### <<Water>>

The boron-containing substance removal liquid contains water. Water may contain a trace amount of components that are unavoidably mixed. The water used in the boron-containing substance removal liquid is preferably water subjected to purification processing such as distilled water, ion exchange water, and ultrapure water and more preferably ultrapure water usually used for manufacturing semiconductors.

The amount of water in the boron-containing substance removal liquid is not particularly limited, and may be the remaining amount excluding the orthoperiodic acid. In a case where the boron-containing substance removal liquid contains optional components described below, the amount of water may be the remaining amount excluding the orthoperiodic acid and the optional components. The amount of water in the boron-containing substance removal liquid is, for example, 30% by mass or greater, 50% by mass or greater, 70% by mass or greater, 75% by mass or greater, 80% by mass or greater, 85% by mass, 90% by mass or greater, 95% by mass or greater, and 99% by mass or greater. The upper limit value of the amount of water in the boron-containing substance removal liquid is, for example, 99.99% by mass or less, 99.5% by mass or less, 99.9% by mass or less, 99.8% by mass or less, 99.5% by mass or less, and 99% by mass or less. The upper limit values and the lower limit values can be optionally combined. The amount of water is preferably 50% to 99.9% by mass with respect to the total mass of the boron-containing substance removal liquid.

### <<Optional Components>>

The boron-containing substance removal liquid may contain optional components in addition to the above-described components within a range where the effects of the present invention are not impaired. Examples of the optional component include an organic solvent, a pH adjuster, a surfactant, and an oxidizing agent.

### Organic Solvent

The boron-containing substance removal liquid may contain an organic solvent within a range where the effect of the present invention is not impaired. As the organic solvent, a water-soluble organic solvent is preferable. The water-soluble organic solvent denotes an organic solvent having high solubility in water, and is, for example, an organic solvent that is compatible with water at a normal temperature under a normal pressure to form a uniform system. Examples of the water-soluble organic solvent include alcohols (such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, 2-methyl-2,4-pentanediol, and 3-methoxy-3-methyl-1-butanol), dimethyl sulfoxide, ethers (such as ethylene glycol dimethyl ether, diethylene glycol dimethyl ether, triethylene glycol dimethyl ether, tetraethylene glycol dimethyl ether, propylene glycol dimethyl ether), and morpholines (such as N-methylmorpholine N-oxide).

The organic solvent may be used alone or in combination of two or more kinds thereof.

In a case where the boron-containing substance removal liquid contains an organic solvent, the amount of the organic solvent is preferably 50% by mass or less, more preferably 30% by mass or less, and still more preferably 10% by mass or less with respect to the total amount of the water and the organic solvent.

The boron-containing substance removal liquid may contain no organic solvent. The boron-containing substance removal liquid may or may not contain a water-soluble organic solvent. The boron-containing substance removal liquid may or may not contain one or more of the above-described compounds described as the water-soluble organic solvent.

### pH Adjuster

The boron-containing substance removal liquid may contain a pH adjuster. The pH adjuster is a component capable of preparing the boron-containing substance removal liquid with a desired pH. As the pH adjuster, it is possible to use an acidic compound or a basic compound.

The acidic compound may be an inorganic acid or an organic acid.

Examples of the inorganic acid include hydrochloric acid, sulfuric acid, sulfurous acid, nitric acid, nitrous acid, phosphoric acid, boric acid, and hexafluorophosphoric acid. The acidic compound may be a salt of an inorganic acid. Examples of the salt of an inorganic acid include an ammonium salt of an inorganic acid. Examples of the ammonium salt of an inorganic acid include ammonium chloride, ammonium sulfate, ammonium sulfite, ammonium nitrate, ammonium nitrite, ammonium phosphate, ammonium borate, and ammonium hexafluorophosphate.

Examples of the organic acid include aliphatic carboxylic acids such as formic acid, acetic acid, propionic acid, butyric acid, lactic acid, oxalic acid, tartaric acid, and citric acid.

The basic compound may be an inorganic base or an organic base.

Examples of the basic inorganic compound include an inorganic compound containing an alkali metal or an alkaline earth metal and a salt thereof. Examples of the basic inorganic compound include lithium hydroxide, sodium hydroxide, potassium hydroxide, rubidium hydroxide, cesium hydroxide, and calcium hydroxide.

Examples of the basic organic compound include a quaternary ammonium salt such as an organic quaternary ammonium hydroxide, and an alkylamine such as trimethylamine or triethylamine. Specific examples of the organic quaternary ammonium hydroxide include tetramethylammonium hydroxide (TMAH), bis(2-hydroxyethyl)dimethylamnnonium hydroxide, tetraethylammonium hydroxide (TEAH), tetrapropylamnnonium hydroxide, tetrabutylammonium hydroxide, methyltriethylanunonium hydroxide, trimethyl(hydroxyethyl)ammonium hydroxide, and triethyl(hydroxyethyl)ammonium hydroxide.

The pH adjuster may be used alone or in combination of two or more kinds thereof.

The pH adjuster can be used in an amount required for adjusting the boron-containing substance removal liquid to have a desired pH. The amount of the pH adjuster in the boron-containing substance removal liquid is, for example, 0% to 10% by mass, 0% to 5% by mass, 0% to 3% by mass, or 0% to 1% by mass with respect to the total mass of the boron-containing substance removal liquid.

The boron-containing substance removal liquid may contain no pH adjuster. The boron-containing substance removal liquid may or may not contain one or more of the above-described compounds described as the pH adjuster.

### Surfactant

The boron-containing substance removal liquid may contain a surfactant for the purpose of adjusting the wettability of the substrate. Examples of the surfactant include a nonionic surfactant, an anionic surfactant, a cationic surfactant, and an amphoteric surfactant.

Examples of the nonionic surfactant include polyalkylene oxide alkylphenyl ether-based surfactants, polyalkylene oxide alkyl ether-based surfactants, block polymer-based surfactants consisting of polyethylene oxide and polypropylene oxide, polyoxyalkylene distyrenated phenyl ether-based surfactants, polyalkylene tribenzylphenyl ether-based surfactants, and acetylene polyalkylene oxide-based surfactants.

Examples of the anionic surfactant include alkylsulfonic acids, alkylbenzenesulfonic acids, alkylnaphthalenesulfonic acids, alkyldiphenyl ether sulfonic acids, fatty acid amidosulfonic acids, polyoxyethylene alkyl ether carboxylic acids, polyoxyethylene alkyl ether acetic acids, polyoxyethylene alkyl ether propionic acids, alkyl phosphonic acids, and fatty acid salts. Examples of “salts” include ammonium salts, sodium salts, potassium salts, and tetramethylammonium salts.

Examples of the cationic surfactant include a quaternary ammonium salt-based surfactant and an alkylpyridinium-based surfactant.

Examples of the amphoteric surfactant include betaine type surfactants, amino acid type surfactants, imidazoline type surfactants, and amine oxide type surfactants.

These surfactants are generally commercially available. The surfactant may be used alone or in combination of two or more kinds thereof.

The amount of the surfactant in the boron-containing substance removal liquid is, for example, 0% to 5% by mass, 0% to 3% by mass, 0% to 1% by mass, or 0% to 0.2% by mass with respect to the total mass of the boron-containing substance removal liquid.

The boron-containing substance removal liquid may contain no surfactant. The boron-containing substance removal liquid may or may not contain one or more selected from the group consisting of a nonionic surfactant, an anionic surfactant, a cationic surfactant, and an amphoteric surfactant. The boron-containing substance removal liquid may or may not contain one or more of the above-described compounds described as a surfactant.

### Oxidizing Agent

The boron-containing substance removal liquid may contain other oxidizing agents in addition to the orthoperiodic acid. Examples of the other oxidizing agents include hydrogen peroxide, nitric acid, sulfuric acid, ozone, a hypochlorite, a transition metal oxide, a peroxide, ammonium cerium nitrate, a nitrate, a nitrite, iodic acid, an iodate, a periodate, a perchlorate, persulfuric acid, a persulfate, peracetic acid, a peracetate, a permanganic acid compound, and a bichromic acid compound.

The other oxidizing agents may be used alone or in combination of two or more kinds thereof. The amount of the other oxidizing agents in the boron-containing substance removal liquid is, for example, 0% to 5% by mass, 0% to 3% by mass, 0% to 1% by mass, or 0% to 0.2% by mass with respect to the total mass of the boron-containing substance removal liquid.

It is preferable that the boron-containing substance removal liquid does not contain other oxidizing agents. The boron-containing substance removal liquid may contain or may not contain one or more of the above-described compounds described as the other oxidizing agents, but it is preferable that the boron-containing substance removal liquid does not contain the above-described compounds.

### Impurities and the Like

The boron-containing substance removal liquid may contain, for example, metal impurities containing metal atoms such as an Fe atom, a Cr atom, a Ni atom, a Zn atom, a Ca atom, and a Pb atom. The total amount of the metal atoms in the boron-containing substance removal liquid is preferably 100 ppt by mass or less with respect to the total mass of the boron-containing substance removal liquid. The lower limit value of the total amount of the metal atoms is preferably as low as possible, but is, for example, 0.001 ppt by mass or greater. The total amount of the metal atoms is, for example, 0.001 ppt by mass to 100 ppt by mass. In a case where the total amount of the metal atoms is set to be less than or equal to the above-described preferable upper limit value, the defect inhibition property and the residue inhibition property of the boron-containing substance removal liquid are improved. It is considered that in a case where the total amount of the metal atoms is set to greater than or equal to the preferable lower limit value, the metal atoms are less likely to be released in the system and less likely to adversely affect the production yield of the entire target to be cleaned.

The amount of the metal impurities can be adjusted, for example, by purification processing such as filtering. The purification processing such as filtering may be 20 performed on a part or all of the raw materials before the preparation of the boron-containing substance removal liquid or after the preparation of the boron-containing substance removal liquid.

The boron-containing substance removal liquid may contain, for example, impurities (organic impurities) derived from an organic substance. The total amount of the organic impurities in the boron-containing substance removal liquid is preferably 5,000 ppm by mass or less. The lower limit of the amount of the organic impurities is preferably as low as possible, and the lower limit is, for example, greater than or equal to 0.1 ppm by mass. The total amount of the organic impurities is, for example, 0.1 ppm by mass to 5,000 ppm by mass.

The boron-containing substance removal liquid may contain, for example, a counting object having a size that can be counted by a light scattering-type liquid-borne particle counter. The size of the counting object is, for example, 0.04 μm or greater. The number of counting objects in the boron-containing substance removal liquid is, for example, 1,000 or less per 1 mL of the boron-containing substance removal liquid, and the lower limit value thereof is, for example, 1 or greater. It is considered that in a case where the number of the counting objects in the boron-containing substance removal liquid is in the above-described range, the metal corrosion inhibition effect of the boron-containing substance removal liquid is improved.

The organic impurities and/or the counting objects may be added to the boron-containing substance removal liquid, or may be inevitably mixed into the boron-containing substance removal liquid in the production step of the boron-containing substance removal liquid. Examples of the case where the organic impurities are inevitably mixed into the production step of the boron-containing substance removal liquid include a case where the raw materials (for example, an organic solvent) used for producing the boron-containing substance removal liquid contain the organic impurities and a case where the organic impurities are mixed from an external environment (for example, contamination) in the production step of the boron-containing substance removal liquid, but the present invention is not limited thereto.

In a case where the counting objects are added to the boron-containing substance removal liquid, the abundance ratio may be adjusted for each specific size in consideration of the surface roughness or the like of the target to be cleaned.

### <<Storage Container>>

A method of storing the boron-containing substance removal liquid is not particularly limited, and a known storage container of the related art can also be used. In order to ensure the stability of the boron-containing substance removal liquid, the void ratio in a container in a case where the boron-containing substance removal liquid is stored in a container, and/or the kind of gas to fill the voids may be appropriately set. For example, the void ratio in the storage container may be in a range of about 0.01% to 30% by volume.

In a case of using the boron-containing substance removal liquid, the boron-containing substance removal liquid may be diluted to 2 to 2,000 times to obtain a diluent, and the step A may be carried out using the diluent.

It is preferable that the boron-containing substance removal liquid does not contain a slurry (metal oxide particles) used in a chemical mechanical polishing (CMP) process. It is preferable that the boron-containing substance removal liquid does not contain a polishing agent. Examples of the polishing agent include metal oxide particles such as alumina, silica, titania, ceria, and zirconia. It is preferable that the boron-containing substance removal liquid does not contain the metal oxide particles as described above.

### <Workpiece>

The workpiece is a workpiece containing a boron-containing substance. The boron contained in the boron-containing substance is, for example, a substance of boron alone. The boron contained in the boron-containing substance may be chemically bonded (for example, a covalent bond, a coordinate bond, or the like) to an atom of another element. The boron-containing substance may contain a substance other than boron, but the main component is preferably boron. The amount of boron in the boron-containing substance is, for example, preferably 60% by mass or greater, more preferably 70% by mass or greater, still more preferably 80% by mass or greater, even still more preferably 90% by mass or greater, and particularly preferably 95% by mass or greater with respect to the total mass of the boron-containing substance. Examples of the substance other than boron which may be contained in the boron-containing substance include silicon. The boron-containing substance may contain, for example, 20% by mass or less, 10% by mass or less, 5% by mass or less, or 3% by mass or less of silicon with respect to the total mass of the boron-containing substance. In a case where the boron-containing film contains silicon, the amount of silicon in the boron-containing substance is, for example, 0.5% by mass or greater, 1% by mass or greater, 1.5% by mass or greater, 2% by mass or greater, or 3% by mass or greater with respect to the total mass of the boron-containing substance. The upper limit values and the lower limit values can be optionally combined. The amount of silicon in the boron-containing substance is, for example, 0% to 20% by mass.

Examples of the boron-containing substance include a boron-containing film. In this case, the workpiece may be a substrate having a surface on which a boron-containing film is formed. Examples of the boron-containing film include a film formed as a hard mask. In this case, the workpiece may be a substrate including a boron-containing film formed as a hard mask. The hard mask may be used as an etching mask or a mask during CMP. In a case where the boron-containing film is a hard mask, the boron-containing film may contain silicon in order to facilitate dry etching. The amount of silicon in the boron-containing film is, for example, the same as described above. The boron-containing substance is not limited to a boron-containing film, and may be fine particles or the like containing boron, and the shape thereof is not particularly limited.

In a case where the workpiece is a substrate including a boron-containing film, a known substrate can be used as the substrate. Examples of the substrate include a substrate used for manufacturing a semiconductor device. Examples of the substrate include a silicon (Si) substrate, a silicon nitride (SiN) substrate, a silicon oxide (SiOx) film substrate, a tungsten (W) substrate, a cobalt (Co) substrate, a titanium nitride (TiN) substrate, a tantalum nitride (TaN) substrate, a germanium (Ge) substrate, a silicon germanium (SiGe) substrate, an aluminum (Al) substrate, a nickel (Ni) substrate, a ruthenium (Ru) substrate, and a copper (Cu) substrate. The substrate may be formed such that a silicon oxide film such as a natural oxide film, a thermal oxide film, or a vapor phase synthesis film (a CVD film or the like) is formed on a surface or a pattern is formed in the silicon oxide film.

The boron-containing film can be formed on a substrate by a known film forming method. Examples of the film forming method include a physical vapor deposition (PVD) method, a chemical vapor deposition (CVD) method, and an atomic layer deposition (ALD) method.

The hard mask layer may include the boron-containing film as a target to be removed in the step A. The hard mask layer may be formed of a boron-containing film. The hard mask layer is a layer formed of a hard mask forming material, and is a layer used as a mask by etching, CMP, or the like.

In a case where the hard mask layer includes the boron-containing film, the boron-containing film as a target to be removed in the step A may be included in the hard mask layer before or after being used as an etching mask.

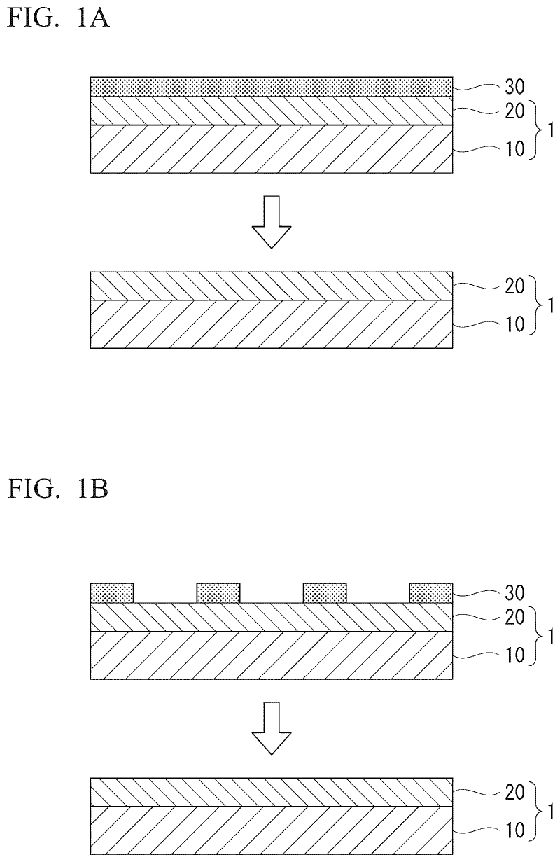

Examples of the hard mask layer before being used as an etching mask include a hard mask layer during rework. FIGS. 1A and 1B show an example of a hard mask layer before being used as an etching mask.

In the upper view of FIG. 1A, a substrate 1 is composed of a non-etching layer 10 and an etching layer 20. A hard mask layer 30 is formed on the etching layer 20. The hard mask layer 30 is composed of the boron-containing film. In the formation of the boron-containing film which is the hard mask layer 30, in a case where a problem occurs in the uniformity of the film or the like, the hard mask layer 30 may be removed to form the hard mask layer 30 again. The hard mask layer 30 in this case is an example of a hard mask layer before being used as an etching mask. The lower view of FIG. 1A shows the substrate after the hard mask layer 30 is removed by the step A. In the substrate in the lower view of FIG. 1A, the boron-containing film can be formed again on the etching layer 20 to form the hard mask layer 30.

In the upper view of FIG. 1B, the hard mask layer 30 is patterned by dry etching or the like. The hard mask layer 30 is composed of the boron-containing film. In the patterning of the boron-containing film which is the hard mask layer 30, in a case where a problem occurs in the formation of a pattern or the like, the hard mask layer 30 may be removed to form the hard mask layer 30 again. The hard mask layer 30 in this case is an example of a hard mask layer before being used as an etching mask. The lower view of FIG. 1B shows the substrate after the hard mask layer 30 is removed by the step A. In the substrate in the lower view of FIG. 1B, the boron-containing film can be formed again on the etching layer 20 to form the hard mask layer 30.

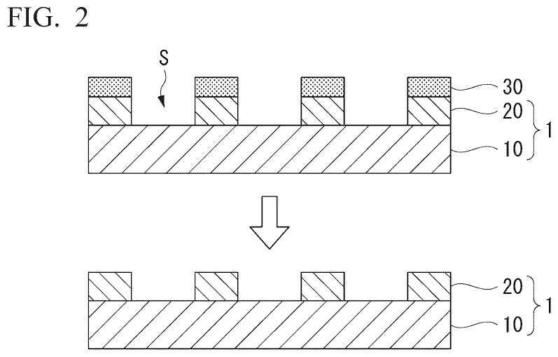

The upper view of FIG. 2 shows an example of the hard mask layer after being used as an etching mask.

In the upper view of FIG. 2, the etching layer 20 is subjected to etching processing using the hard mask layer 30 as an etching mask. The hard mask layer 30 is composed of the boron-containing film. The hard mask layer 30 in this case is an example of the hard mask layer after being used as an etching mask. The lower view of FIG. 2 shows the substrate after the hard mask layer 30 is removed by the step A.

In some embodiments, a conductive material or the like is deposited on a space portion S of a pattern of the etching layer 20 formed by the etching processing so that the space portion S is embedded, and the hard mask layer 30 is removed by the step A. Examples of such a step include steps shown in FIGS. 13 to 16 of Published Japanese Translation No. 2013-533376 of the PCT International Publication for Patent Applications. A conductive material or the like is deposited on the space portion S of the pattern of the etching layer 20 formed by the etching processing so that the space portion S and the hard mask layer 30 are embedded to form an embedded layer. Next, the embedded layer is flattened until the hard mask layer 30 is exposed by the CMP process. Thereafter, the hard mask layer 30 is removed by the step A. Examples of an embedding material include titanium nitride (TiN), tantalum nitride (TaN), silicon nitride (SiN), titanium oxide (TiO₂), tantalum oxide (Ta₂O₅), and silicon oxide (SiOx (1≤x≤2)).

The workpiece may have, on the surface thereof, a region containing at least one selected from the group consisting of a titanium atom, a tantalum atom, and a silicon atom. The region is a region that does not contain boron. The atom may be a simple substance or a compound. Examples of the compound of the atom include a nitride and an oxide. Examples of the nitride include titanium nitride (TiN), tantalum nitride (TaN), and silicon nitride (SiN). Examples of the oxide include titanium oxide (TiO₂), tantalum oxide (Ta₂O₅), and silicon oxide (SiOx (1≤x≤2)).

The workpiece may have, on the surface thereof, a first region containing a boron-containing substance and a second region containing at least one selected from the group consisting of a titanium atom, a tantalum atom, and a silicon atom. The second region is a region that does not contain boron.

The first region may be a region having a boron-containing film or may be a region where a boron-containing film is formed as a hard mask. The first region can be a region formed of the hard mask layer 30 in FIGS. 1A, 1B, and 2.

The second region is preferably a region containing a compound (a nitride, an oxide, or the like) of titanium, tantalum, or silicon. The second region may be a region where a compound film (a nitride film, an oxide film, or the like) of titanium, tantalum, or silicon is formed, or a region where the compound film is subjected to etching processing. The second region may be a region to be etched by using the hard mask layer as an etching mask. The second region can be a region formed of the etching layer 20 in FIG. 1B. The second region may be a region after being etched using the hard mask as an etching mask. The second region can be a region formed of the etching layer 20 in FIG. 2. The etching layer 20 can be formed on the non-etching layer 10 by a known film forming method such as a CVD method, a PVD method, or an ALD method. The second region may be a region exposed after being etched using the hard mask layer as an etching mask. The second region can be a region formed of the non-etching layer 10 in FIG. 2. The second region may be a region having an embedded layer formed in a space portion of a pattern of the etching layer. The pattern of the etching layer can be obtained by performing the etching processing on the etching layer using the hard mask layer as an etching mask. In FIG. 2, the embedded layer can be formed to cover the space portion of the etching layer 20 and the hard mask layer 30 by a known film forming method such as a CVD method, a PVD method, or an ALD method. Next, the embedded layer is flattened by the CMP process until the hard mask layer 30 is exposed, and thus the embedded layer can be formed as the second region.

The boron-containing substance removal liquid used in the step A hardly exhibits removal performance with respect to a compound (a nitride, an oxide, or the like) of titanium, tantalum, or silicon. Therefore, in the workpiece having the first region and the second region, the boron-containing substance in the first region can be removed without damaging the second region.

### <Contact Between Boron-Containing Substance Removal Liquid and Workpiece>

A method of bringing the boron-containing substance removal liquid into contact with the workpiece is not particularly limited, and a known method can be used. Examples of such a method include a method of continuously coating the workpiece rotating at a constant speed with the boron-containing substance removal liquid (a spin coating method), a method of immersing the workpiece in the boron-containing substance removal liquid for a certain period of time (a dipping method), a method of spraying the boron-containing substance removal liquid onto the surface of the workpiece (a spraying method), and a method of raising up the boron-containing substance removal liquid on the surface of the workpiece by the surface tension and allowing the liquid to stand for a certain period of time (a puddle method).

The rotation speed of the workpiece in the spin coating method is, for example, 100 to 5,000 rpm, 500 to 3,000 rpm, or 800 to 2,000 rpm.

In the dipping method, the boron-containing substance removal liquid may be stirred during the immersion of the workpiece in the boron-containing substance removal liquid. The stirring speed thereof is, for example, 50 to 1,000 rpm, 100 to 500 rpm, or 200 to 400 rpm.

The temperature (processing temperature) of the boron-containing substance removal liquid during the contact is not particularly limited. The temperature of the boron-containing substance removal liquid is, for example, 10° C. to 80° C., 15° C. to 70° C., 20° C. to 65° C., or 20° C. to 60° C. By increasing the processing temperature, the boron-containing substance removal performance of the boron-containing substance removal liquid is improved, but the processing temperature can be appropriately selected in consideration of the workability, the safety, the cost, and the like. The processing temperature can be set to, for example, 60° C. or lower. It is preferable that the boron-containing substance removal liquid is heated to a desired processing temperature before the contact with the workpiece. The above-described temperature is the temperature of the boron-containing substance removal liquid at the atmospheric pressure.

A time sufficient for removing the boron-containing substance as a target to be removed can be appropriately selected as the contact time. The contact time is, for example, 10 seconds or longer, 30 seconds or longer, 1 minute or longer, 5 minutes or longer, 10 minutes or longer, 15 minutes or longer, 20 minutes or longer, 25 minutes or longer, or 30 minutes or longer. The upper limit of the contact time is not particularly limited, but is, for example, 10 hours or shorter, 8 hours or shorter, 5 hours or shorter, 3 hours or shorter, 2 hours or shorter, or 1 hour or shorter from the viewpoints of work efficiency and the like. The upper limit values and the lower limit values can be optionally combined. The contact time is, for example, 10 seconds or greater and 10 hours or shorter.

### [Optional Steps]

The method of the present embodiment may include optional steps in addition to the step A. Examples of the optional steps include a step of cleaning the workpiece (cleaning step) and a step of drying the workpiece (drying step).

The cleaning step can be performed after the step A using a known cleaning liquid. Examples of the cleaning liquid include water. The cleaning can be performed by bringing the cleaning liquid into contact with the workpiece by a spin coating method, a dipping method, a spraying method, a puddle method, or the like. The cleaning can be carried out at room temperature (about 15° C. to 30° C.) and the atmospheric pressure. The contact time between the cleaning liquid and the workpiece is, for example, 10 to 180 seconds, 20 to 120 seconds, or 30 to 60 seconds.

The drying step can be performed on the workpiece after the step A or after the step A and the cleaning step. Examples of the drying method include natural drying and drying by blowing nitrogen.

In the workpiece processing method according to the present embodiment, the boron-containing substance is removed from the workpiece by using the boron-containing substance removal liquid containing orthoperiodic acid and water. The boron-containing substance removal liquid contains orthoperiodic acid as an oxidizing agent, and thus can efficiently remove the boron-containing substance from the workpiece. The boron-containing substance removal liquid has a high etching rate with respect to the boron-containing substance even at a processing temperature of 60° C. or lower. Therefore, the boron-containing substance can be removed from the workpiece at a low processing temperature (for example, 20° C. to 60° C.).

In addition, the boron-containing substance removal liquid has an extremely low etching rate with respect to a region (for example, a region containing a nitride or oxide of titanium, tantalum, or silicon) containing at least one selected from the group consisting of a titanium atom, a tantalum atom, and a silicon atom. Therefore, in a workpiece having such a region, the boron-containing substance can be removed from the workpiece while damage to the region is suppressed.

### (Removal Liquid for Removing Boron-Containing Substance: Boron-Containing Substance Removal Liquid)

The removal liquid (boron-containing substance removal liquid) for removing the boron-containing substance from the workpiece containing the boron-containing substance according to a second aspect of the present invention contains orthoperiodic acid and water.

Examples of the boron-containing substance removal liquid of the present embodiment include the same liquid as the boron-containing substance removal liquid used in the step A of the workpiece processing method according to the first aspect.

Examples of the workpiece containing a boron-containing substance, to which the boron-containing substance removal liquid of the present embodiment is applied, include the same workpiece as the workpiece, to which the workpiece processing method according to the first aspect is applied.

The boron-containing substance removal liquid according to the present embodiment contains orthoperiodic acid as an oxidizing agent, and thus can efficiently remove the boron-containing substance from the workpiece.

### (Substrate Processing Method)

A substrate processing method according to a third aspect of the present invention includes a step of forming an etching mask including a boron-containing film on a substrate (hereinafter, also referred to as “step (i)”), a step of performing etching of the substrate using the etching mask (hereinafter, also referred to as “step (ii)”), and a step of bringing the boron-containing substance removal liquid according to the second aspect into contact with the boron-containing film after the etching to remove the boron-containing film (hereinafter, also referred to as “step (iii)”).

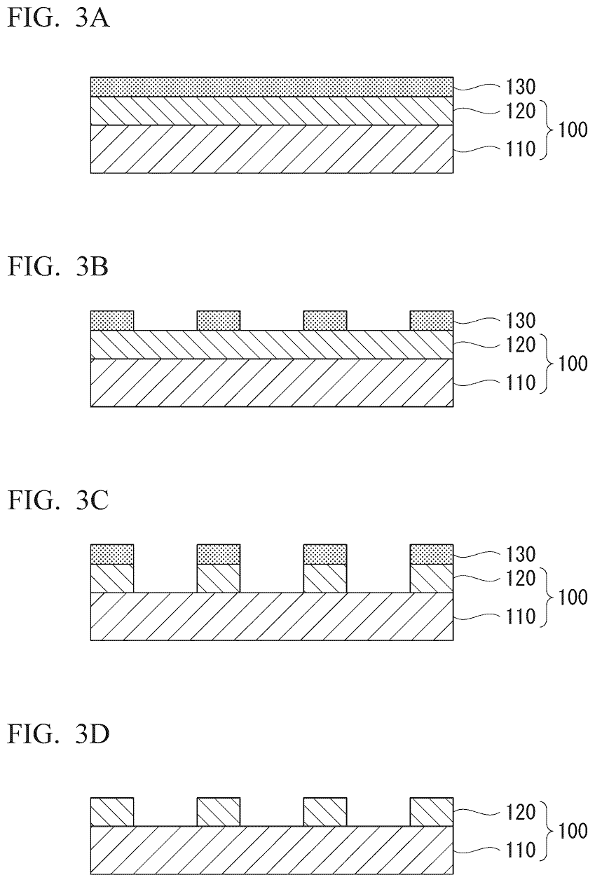

FIGS. 3A to 3D are schematic views for describing an example of the substrate processing method of the present embodiment. In FIGS. 3A to 3D, a substrate 100 includes a non-etching layer 110 and an etching layer 120. The etching layer 120 is a portion of the substrate as a target to be etched in the step (ii). The non-etching layer 110 and the etching layer 120 may be formed of the materials that are the same as or different from each other.

The etching layer 120 may be an inorganic layer formed on the non-etching layer 110. Examples of the inorganic layer include an oxide film of an element constituting the substrate (non-etching layer 110) and a film or layer of an inorganic substance (for example, SiN, SiOx, W, Co, TiN, TaN, Ge, SiGe, Al, Al₂O₃, Ni, Ru, or Cu) formed on the surface of the substrate (non-etching layer 110), in addition to the substrate.

In the substrate processing method shown in FIGS. 3A to 3D, first, a hard mask layer 130 including a boron-containing film is formed on the substrate 100 (FIG. 3A), and the hard mask layer 130 is processed to form an etching mask (FIG. 3B) (step (i)).

Next, the etching layer 120 of the substrate 100 is subjected to etching processing using the processed hard mask layer 130 as an etching mask (step (ii); FIG. 3C).

Next, the hard mask layer 130 is removed using the boron-containing substance removal liquid according to the second aspect (step (iii); FIG. 3D).

[Step (i)]

In the step (i), an etching mask including a boron-containing film is formed on the substrate.

In FIG. 3A, the hard mask layer 130 including a boron-containing film is formed on the etching layer 120. The hard mask layer 130 may be formed of a boron-containing film or may include other films in addition to the boron-containing film, but is preferably formed of only a boron-containing film. The method of forming the boron-containing film is not particularly limited, and a known film forming method such as a CVD method, a PVD method, or an ALD method can be used. Examples of the boron-containing film formed here include the same films as those described in the first aspect. The boron-containing film may contain about 0.5% to 10% by mass (preferably about 1% to 5% by mass) of silicon in order to facilitate dry etching in a case of processing into an etching mask. In a case where the hard mask layer 130 includes a film other than the boron-containing film (a film formed of a material other than the boron-containing substance), the other film can also be formed by a known film forming method such as a CVD method, a PVD method, or an ALD method.

In FIG. 3B, the hard mask layer 130 is processed to form an etching mask. The hard mask layer 130 can be processed by a known method. Examples of a method of processing the hard mask layer 130 include dry etching. Examples of the dry etching method include a processing method using ozone plasma and a method of performing heat processing using a laser or the like in an oxygen gas or ozone gas oxidation atmosphere (Japanese Patent No. 6914107). The hard mask layer 130 may be etched using, for example, a resist pattern as a mask.

[Step (ii)]

In the step (ii), the substrate is etched using the etching mask formed in the step (i).

In FIG. 3C, the etching layer 120 is etched using, as an etching mask, the hard mask layer 130 processed into an etching mask. The etching layer 120 can be etched by, for example, dry etching. Examples of the etching gas include fluorinated carbon-based gases such as tetrafluoromethane (CF₄) gas and trifluoromethane (CHF₃) gas, chlorine-based gases such as chlorine (Cl₂) gas, oxygen gas, and ozone gas, but the present invention is not limited thereto.

[Step (iii)]

In the step (iii), the boron-containing film is removed by bringing the boron-containing substance removal liquid according to the second aspect into contact with the boron-containing film after the etching.

In FIG. 3D, the boron-containing substance removal liquid according to the second aspect is brought into contact with the hard mask layer 130 used as an etching mask to remove the hard mask layer 130. The boron-containing substance removal liquid can be brought into contact with the hard mask layer 130 in the same manner as in the step A in the workpiece processing method according to the first aspect.

In a case where the hard mask layer 130 includes a film other than the boron-containing film, the film may be removed by bringing a removal liquid suitable for the material of the film into contact with the film.

### [Optional Steps]

The method of the present embodiment may include optional steps in addition to the steps (i) to (iii). Examples of the optional steps include a resist film forming step, a resist film exposing step, and a resist film developing step. In addition, examples of the optional step include known steps performed in a case of manufacturing a semiconductor element. Examples of such a step include a step of forming each structure such as a capacitor, a channel, a High-K/metal gate, a metal wire, a gate structure, a source structure, a drain structure, an insulating layer, a ferromagnetic layer, or a non-magnetic layer (layer formation, etching other than the above-described etching processing, chemical mechanical polishing, modification, or the like), a heat processing step, and an inspection step.

According to the method of the present embodiment, the boron-containing film used as an etching mask is removed by using the boron-containing substance removal liquid according to the second aspect. Therefore, the boron-containing film used as the etching mask can be efficiently removed. The boron-containing substance removal liquid can remove the boron-containing substance even at a processing temperature of 60° C. or lower, and thus, the substrate is not required to be heated to a high temperature (for example, 70° C. or higher) in a case of performing removal processing of the boron-containing film.

In addition, the boron-containing substance removal liquid has an extremely low etching rate with respect to a region (for example, a region having a nitride film or oxide film of titanium, tantalum, or silicon) containing at least one selected from the group consisting of a titanium atom, a tantalum atom, and a silicon atom. Therefore, the present invention can be suitably applied to a substrate having such a region.

### EXAMPLES

Hereinafter, the present invention will be described in more detail based on examples, but the present invention is not limited to these examples.

### Examination of Oxidizing Agent

### Preparation of Boron-Containing Substance Removal Liquid

### Example 1 and Comparative Examples 1 to 5

Each oxidizing agent component listed in Table 1 was dissolved in water such that the concentration thereof reached 0.044 mol/L, thereby preparing a boron-containing substance removal liquid of each example.

### [Measurement (1) of Etching Rate of Boron Film]

As the substrate, a substrate (boron film-containing substrate) on which a boron film (350 nm) was formed on a 12-inch silicon substrate by a PVD method was used. The boron film-containing substrate was cut into 1.5 cm×1.5 cm to prepare a wafer coupon. 50 mL of the boron-containing substance removal liquid of each example was poured into a disposable cup, the temperature condition was set to room temperature (24° C.), and the wafer coupon was immersed in the boron-containing substance removal liquid. During the immersion of the wafer coupon, the temperature condition was set to room temperature (24° C.), and the boron-containing substance removal liquid was not stirred.

After the immersion for 30 minutes, the wafer coupon was taken out from the boron-containing substance removal liquid, cleaned with water at room temperature for 30 seconds, and dried by blowing nitrogen gas.

The film thickness of the wafer coupon before and after the immersion in the boron-containing substance removal liquid was measured. The film thickness was measured using a fluorescence X-ray device (ZSX Primus IV, manufactured by Rigaku Corporation). The etching rate was calculated front a change in the film thickness of the boron film before and after the immersion in the boron-containing substance removal liquid. The results are listed in the columns of “E.R.” in Table 1.

TABLE 1

| | Oxidizing agent | |
|---|---|---|
| | component | E.R. (nm/min) |
| Example 1 | H₅IO₆ | 10.1 |
| Comparative Example 1 | HNO₃ | 0.3 |
| Comparative Example 2 | (NH₄)₂S₂O₈ | 0.3 |
| Comparative Example 3 | HIO₃ | 0.2 |
| Comparative Example 4 | H₂O₂ | 0.2 |
| Comparative Example 5 | NaClO | 0.2 |

The oxidizing agent components listed in Table 1 are as follows.
H₅IO₆: orthoperiodic acid
HNO₃: nitric acid
(NH₄)₂S₂O₈: ammonium peroxodisulfate
HIO₃: iodic acid
H₂O₂: hydrogen peroxide
NaClO: sodium hypochlorite

As shown in the results listed in Table 1, it was confirmed that the etching rate of the boron film was improved in Example 1 as compared with Comparative Examples 1 to 5.

### Examination of Concentration of Orthoperiodic Acid and Processing Temperature

### Preparation of Boron-Containing Substance Removal Liquid

### Examples 2 to 9

The orthoperiodic acid was dissolved in water such that the concentration was as listed in Table 2, thereby preparing a boron-containing substance removal liquid of each example.

### [Measurement (2) of Etching Rate of Boron Film]

The etching rate of the boron film was measured in the same manner as described in the section of [Measurement (1) of etching rate of boron film] above except that the temperature of the boron-containing substance removal liquid was set to room temperature (24° C.), 40° C., or 60° C. and the boron-containing substance removal liquid was stirred at 300 rpm during the immersion of the wafer coupon. The results are listed in the columns of “E.R.” in Table 2.

TABLE 2

| | | Concentration of | Room | | |
|---|---|---|---|---|---|
| | Oxidizing | oxidizing agent | temperature | 40° C. | 60° C. |
| | agent | component | E.R. | E.R. | E.R. |
| | component | (% by mass) | (nm/min) | (nm/min) | (nm/min) |
| Example 2 | H₅IO₆ | 0.1 | 3.2 | 8.6 | 16.7 |
| Example 3 | H₅IO₆ | 0.2 | 8.9 | 24.0 | 31.6 |
| Example 4 | H₅IO₆ | 0.5 | 17.9 | 54.0 | 80.3 |
| Example 5 | H₅IO₆ | 1 | 21.7 | 82.1 | 184.5 |
| Example 6 | H₅IO₆ | 5 | 50.6 | 159.0 | 449.8 |
| Example 7 | H₅IO₆ | 10 | 65.6 | 221.3 | 805.5 |
| Example 8 | H₅IO₆ | 25 | 85.2 | 297.8 | 1059.4 |
| Example 9 | H₅IO₆ | 50 | 87.5 | 351.0 | 1546.2 |

As shown in the results listed in Table 2, it was confirmed that the etching rate of the boron film increased as the concentration of the orthoperiodic acid in the boron-containing substance removal liquid increased. In addition, it was confirmed that the etching rate of the boron film increased as the temperature of the boron-containing substance removal liquid during the immersion processing increased.

### <Examination of Stability>

### [Evaluation of Stability]

The boron-containing substance removal liquid of Example 5 was poured into a poly bottle and heated at 60° C. for 5 days. At the start of heating (0 hours) and on the first day, second day, and fifth day after the start of heating, the boron-containing substance removal liquid was sampled from the poly bottle. The concentration of the orthoperiodic acid and the etching rate of the boron film were measured for the sampled boron-containing substance removal liquid.

### [Measurement (3) of Etching Rate of Boron Film]

The etching rate of the boron film was measured in the same manner as described in the section of [Measurement (1) of etching rate of boron film] above except that the temperature of the boron-containing substance removal liquid was set to 60° C. and the boron-containing substance removal liquid was stirred at 300 rpm during the immersion in the wafer coupon. The results are listed in the columns of “E.R.” in Table 3.

### [Measurement of Orthoperiodic Acid]

The concentration of the orthoperiodic acid in the boron-containing substance removal liquid was measured using an automatic titrator (OMNIS, manufactured by Metrohm AG).

TABLE 3

| | | |
|---|---|---|
| Time for | | |
| maintaining | | |
| performance | Concentration | |
| during heating | of H₅IO₆ | E.R. |
| at 60° C. | (% by mass) | (nm/min) |

| | | | | |
|---|---|---|---|---|
| Example 5 | 0 | hours | 0.97 | 185 |
| | 1 | day | 0.97 | 183 |
| | 2 | days | 0.98 | 190 |
| | 5 | days | 0.97 | 187 |

As shown in the results listed in Table 3, it was confirmed that the boron-containing substance removal liquid of Example 5 stably maintained the concentration of orthoperiodic acid and the etching performance for the boron film during the storage period of 5 days at 60° C.

### <Examination of Etching Rate of Si-Containing Boron Film>

### [Measurement of Etching Rate of Boron Film and Si-Containing Boron Film]

As the boron-containing substance removal liquid, the boron-containing substance removal liquid of Example 5 was used.

In addition to the boron film-containing substrate, a Si-containing boron film-containing substrate was used. As the Si-containing boron film-containing substrate, a substrate on which a boron film (Si-containing boron film) (350 nm) containing 3% by mass of silicon (Si) was formed by a plasma CVD method on a 12-inch silicon substrate was used. The boron film-containing substrate and the Si-containing boron film-containing substrate were cut into 1.5 cm×1.5 cm to prepare a wafer coupon of each substrate.

The etching rate of the boron film was measured in the same manner as described in the section of [Measurement (2) of etching rate of boron film] except that the wafer coupon of the boron film-containing substrate and the wafer coupon of the Si-containing boron film-containing substrate were used. The results are listed in the columns of “E.R.” in Table 4.

TABLE 4

| | | Room | 40° C. | 60° C. |
|---|---|---|---|---|
| | Target to be | temperature | E.R. | E.R. |
| | etched | E.R. (nm/min) | (nm/min) | (nm/min) |
| Example 5 | Boron film | 22 | 82 | 185 |
| | Si-containing | 18 | 42 | 110 |
| | boron film | | | |

As shown in the results listed in Table 4, it was confirmed that the boron-containing substance removal liquid of Example 5 also had etching performance for the Si-containing boron film.

### Examination of Damage to Titanium Nitride

### Preparation of Boron-Containing Substance Removal Liquid

### Comparative Example 6

A boron-containing substance removal liquid of Comparative Example 6 was prepared by dissolving hydrogen peroxide in water so that the concentration thereof reached 31% by mass. The concentration of hydrogen peroxide was determined with reference to the etching rate for the boron film disclosed in Japanese Patent No. 7142461.

### [Measurement of Etching Rate of Titanium Nitride Film]

As the boron-containing substance removal liquid, the boron-containing substance removal liquids of Example 5 and Comparative Example 6 were used.

As the substrate, a substrate (TiN film-containing substrate) on which a titanium nitride film (50 nm) was formed by a PVD method on a 12-inch silicon substrate was used. The TiN film-containing substrate was cut into 1.5 cm×1.5 cm to prepare a wafer coupon.

The etching rate of the TiN film was measured in the same manner as described in the section of [Measurement (2) of etching rate of boron film] except that the wafer coupon of the TiN film-containing substrate was used and the temperature of the boron-containing substance removal liquid was set to 24° C. or 60° C. during the immersion of the wafer coupon. The results are listed in the columns of “TiN E.R.” in Table 5.

TABLE 5

| | Processing | TiN E.R. |
|---|---|---|
| | temperature | (nm/min) |
| Example 5 | 24° C. | <0.1 |
| | 60° C. | <0.1 |
| Comparative Example 6 | 60° C. | 14.8 |

As shown in the results listed in Table 5, it was shown that the etching of the TiN film by the boron-containing substance removal liquid of Example 5 hardly occurred at any of the processing temperatures of 24° C. and 60° C. As shown in the results, it was confirmed that the boron-containing substance removal liquid of Example 5 did not damage the TiN film. On the contrary, the boron-containing substance removal liquid of Comparative Example 6 had a high etching rate for the TiN film, and caused damage to the TiN film.

### <Examination of Damage to Various Compounds>

### [Measurement of Etching Rate of Various Compound Films]

As the boron-containing substance removal liquid, the boron-containing substance removal liquids of Example 5 and Comparative Example 6 were used.

As the substrate, a substrate on which any of the following films was formed on a 12-inch silicon substrate was used. These substrates were cut into 1.5 cm×1.5 cm to prepare a wafer coupon.
Th-SiO₂ film: thermal oxide film of silicon dioxide (film thickness: 100 nm)
P-TEOS film: silicon oxide film (film thickness: 500 nm) formed by plasma CVD method
ALD-SiN film: silicon nitride film (film thickness: 40 nm) formed by ALD method
PVD-TiN film: titanium nitride film (film thickness: 50 nm) formed by PVD method
PVD-TaN film: tantalum nitride film (film thickness: 10 nm) formed by PVD method

The etching rate of the metal atom-containing film was measured in the same manner as described in the section of [Measurement (2) of etching rate of boron film] except that the temperature of the boron-containing substance removal liquid was set to 60° C. during the immersion of the wafer coupon using the wafer coupon. The results thereof are listed in the columns of “E.R.” in Table 6.

TABLE 6

| | E.R. (nm/min) | | | | |
|---|---|---|---|---|---|
| | Th-SiO2 | P-TEOS | ALD-SiN | PVD-TiN | PVD-TaN |
| Example 5 | <0.1 | <0.1 | <0.1 | <0.1 | <0.1 |

As shown in the results listed in Table 6, it was shown that etching of the various tested compound-containing films by the boron-containing substance removal liquid of Example 5 hardly occurred. As shown in the results, it was confirmed that the boron-containing substance removal liquid of Example 5 did not damage these compound-containing films.

Although the preferable examples of the present invention have been described above, the present invention is not limited to these examples. Additions, omissions, substitutions, and other modifications can be made without departing from the scope of the present invention. Accordingly, the present invention is not limited by the description above and is only limited by the scope of the appended claims.

### REFERENCE SIGNS LIST

1, 100 Substrate
10, 110 Non-etching layer
20, 120 Etching layer
30, 130 Hard mask layer

What is claimed is:

1. A workpiece processing method comprising:
bringing a boron-containing substance removal liquid containing orthoperiodic acid and water into contact with a workpiece containing a boron-containing substance to remove the boron-containing substance from the workpiece.

2. The processing method according to claim 1, wherein the workpiece is a substrate having a surface on which a boron-containing film is formed.

3. The processing method according to claim 2, wherein the boron-containing film is a film formed as a hard mask.

4. The processing method according to claim 3, wherein the boron-containing film is a hard mask layer before or after being used as an etching mask.

5. The processing method according to claim 1, wherein the boron-containing substance contains silicon.

6. The processing method according to claim 1, wherein the workpiece further comprises, on a surface thereof, a region containing at least one selected from the group consisting of a titanium atom, a tantalum atom, and a silicon atom.

7. A removal liquid comprising:
orthoperiodic acid; and
water,
wherein the removal liquid is used for removing a boron-containing substance from a workpiece containing the boron-containing substance.

8. The removal liquid according to claim 7, wherein the workpiece is a substrate having a surface on which a boron-containing film is formed.

9. The removal liquid according to claim 8, wherein the boron-containing film is included in a hard mask layer.

10. The removal liquid according to claim 8, wherein the boron-containing film is included in a hard mask layer before or after being used as an etching mask.

11. The removal liquid according to claim 7, wherein the workpiece contains silicon.

12. The removal liquid according to claim 7, wherein the workpiece further comprises, on a surface thereof, a region containing at least one selected from the group consisting of a titanium atom, a tantalum atom, and a silicon atom.

13. A substrate processing method comprising:
forming an etching mask including a boron-containing film on a substrate;
performing etching on the substrate using the etching mask; and
bringing the removal liquid according to claim 8 into contact with the boron-containing film after the etching to remove the boron-containing film.
